(19) United States
(12) Patent Application Publication
(10) Pub. No.: US 2009/0039421 A1
(43) Pub. Date: Feb. 12, 2009

(54) Nitride semiconductor device and method for producing nitride semiconductor device

(75) Inventor: Hirotaka Otake, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/213,099

(22) Filed: Jun. 13, 2008

(30) Foreign Application Priority Data
Jun. 15, 2007 (JP) 2007-158800

(51) Int. Cl. H01L 29/94; H01L 21/336

(52) U.S. Cl. 257/329; 438/268; 257/E21.442

(57) ABSTRACT

A nitride semiconductor device of the present invention includes a nitride semiconductor laminated structure comprising an n type first layer, a second layer containing a p type dopant laminated on the first layer, and an n type third layer laminated on the second layer, each layer of the nitride semiconductor laminated structure made of a group III nitride semiconductor, and the nitride semiconductor laminated structure having a wall surface extending the first, through the second, to the third layers; a gate insulating film formed on the wall surface such that the gate insulating film extends for the first, second, and third layers; a gate electrode formed such that the gate electrode is opposed to the wall surface of the second layer with the gate insulating film sandwiched between the gate electrode and the wall surface;

a source electrode electrically connected to the third layer; and a drain electrode electrically connected to the first layer, the wall surface including a plurality of portions having different inclination angles to a lamination interface of the nitride semiconductor laminated structure.

### BACKGROUND OF THE INVENTION

1. Field of the Invention

The present invention relates to a nitride semiconductor device using a Group III nitride semiconductor and a manufacturing method thereof.

2. Description of Related Art

Conventionally, a power device using a silicon semiconductor is used for a power amplifier circuit, a power supply circuit, a motor drive circuit, or the like.

However, from theoretical limitations of the silicon semiconductor, high withstand voltage, low resistance, and high speed of the silicon device have nearly reached their limits, which leads to difficulties in satisfying market needs.

Therefore, consideration has been given to the development of a nitride semiconductor device having characteristics such as high withstand voltage, high-temperature operation, a large current density, high-speed switching, low on-resistance, and the like.

FIG. 5 is a diagrammatic sectional view for describing a structure according to a conventional field effect transistor.

This field effect transistor 80 includes a sapphire substrate 81 and a laminated structure portion 93 having an npn structure including an undoped GaN layer 82, an n type GaN layer 83, a p type GaN layer 84, and an n type GaN layer 85 laminated in order from the side of the sapphire substrate 81. In the laminated structure portion 93, a mesa-like laminated portion 92 is formed by etching up to the middle of the n type GaN layer 83 from the top surface of the n type GaN layer 85. Both side surfaces of this mesa-like laminated portion 92 are inclined surfaces 91 inclined at a predetermined inclination angle to the lamination interfaces of the laminated structure portion 93. A gate insulating film 86 made of SiO₂ (silicon oxide) is formed on the surface of the mesa-like laminated portion 92 (including the inclined surfaces 91) and the surface of the n type GaN layer 83 exposed by etching. In the gate insulating film 86, contact holes are formed for partially exposing the n type GaN layer 85 and the n type GaN layer 83. A source electrode 88 is formed on the top surface of the n type GaN layer 85 exposed from the contact hole. The source electrode 88 is electrically connected to the n type GaN layer 85. On the other hand, a drain electrode 89 is formed on the upper surface of then type GaN layer 83 exposed from the contact hole. The drain electrode 89 is electrically connected to the n type GaN layer 83. Gate electrodes 87 are formed on the gate insulating film 86, at the portions opposed to the inclined surfaces 91. Then, the source electrode 88, the drain electrode 89, and the gate electrode 87 are insulated from each other by interposed of interlayer dielectric films 90 made of polyimide between each of the adjacent electrodes.

Next, an operation of this field effect transistor 80 is described. For example, a bias voltage is applied to between the source electrode 88 and the drain electrode 89, such that the drain electrode 89 is positive. Accordingly, a reverse voltage is applied to the pn junction in the interface between the n type GaN layer 83 and the p type GaN layer 84. As a result, between the n type GaN layer 85 and the n type GaN layer 83, that is, between the source and the drain are nonconductive state (reverse bias state). From this state, a bias voltage equal to or more than a predetermined voltage value (gate threshold voltage) being positive to the potential of the source electrode 88 regarded as a reference potential is applied to the gate electrode 87. Accordingly, electrons are induced in a region (channel region) near the inclined surface 91 of the p type GaN layer 84 and an inversion layer (channel) is formed. Then, via this inversion layer, conduction is provided between the source and drain. Thus, a transistor operation of the field effect transistor 80 is realized.

The inclined surfaces 91 preferably have less polarization charge. In other words, the inclined surfaces 91 are preferably nonpolar or close to nonpolar planes. For example, in the case where the lamination interface of the laminated structure portion 93 is a c-plane (polar plane), when the inclined surfaces 91 are steep (nonpolar or close to nonpolar planes) to the c-plane, generation of polarization charge near the interfaces between the inclined surfaces 91 of the p type GaN layer 84 and the gate insulating film 86 (the channel regions) can be suppressed. Therefore, the channel mobility of the field effect transistor 80 can be improved.

However, when the inclined surfaces 91 are steep to the lamination interfaces of the laminated structure portion 93, in the reverse bias state, electric fields concentrate in the portions near the boundaries between the inclined surfaces 91 and the top surface of the n type GaN layer 85 (the upper end portions of the mesa-like laminated portion 92 indicated by the arrows A and D) and the portions near the boundary between the inclined surfaces 91 and the upper surface of the n type GaN layer 83 (the lower end portions of the mesa-like laminated portion 92 indicated by the arrows B and C). Therefore, breakdown may occur even with a low drain voltage.

### SUMMARY OF THE INVENTION

An object of the present invention is to provide a nitride semiconductor device and a method for producing the same which can suppress generation of polarization charge at the portions where channels are formed and prevent breakdown.

The nitride semiconductor device of the present invention includes a nitride semiconductor laminated structure comprising an n type first layer, a second layer containing a p type dopant laminated on the first layer, and an n type third layer laminated on the second layer, each layer of the nitride semiconductor laminated structure made of a group III nitride semiconductor, and the nitride semiconductor laminated structure having a wall surface extending the first, through the second, to the third layers, a gate insulating film formed on the wall surface such that the gate insulating film extends for the first, second, and third layers, a gate electrode formed such that the gate electrode is opposed to the wall surface of the second layer with the gate insulating film sandwiched between the gate electrode and the wall surface,

a source electrode electrically connected to the third layer, and a drain electrode electrically connected to the first layer, the wall surface including a plurality of portions having different inclination angles to a lamination interface of the nitride semiconductor laminated structure.

According to this configuration, the nitride semiconductor laminated structure having an npn structure is formed by laminating the n type first layer, the second layer containing a p type dopant, and the n type third layer. In the nitride semiconductor laminated structure, wall surface extending from the first to third layers is formed. On this wall surface, a gate insulating film is arranged so as to extend for the first through third layers. The portion near the interface between the wall surface and the gate insulating film on the second layer forms a channel region. The gate electrode is opposed to this channel region. Further, the wall surface extending from the first to third layers includes a plurality of portions having different inclination angles to a lamination interface of the nitride semiconductor laminated structure. In addition, the drain electrode is provided so as to be electrically connected to the first layer. The source electrode is provided so as to be electrically connected to the third layer.

The inclination angle means the angle on the inside out of the angle on the inside and the angle on the outside of the nitride semiconductor laminated structure by setting the line of intersection of the wall surface and the lamination interface of the nitride semiconductor laminated structure as a boundary. The wall surface may be a curved surface having a plurality of portions having different inclination angles. The wall surface may have a plurality of inclined planes having different inclination angles. The drain electrode and the source electrode are electrically connected to the first layer and the third layer, respectively, and two or more semiconductor layers having different compositions or containing different dopants may be laminated between these electrodes and the semiconductor layer.

The wall surface extending from the first to third layers includes a plurality of portions having different inclination angles, so that on the wall surface, for example, the inclination angle of the second layer portion opposed to the gate electrode can be set regardless of the inclination angles of portions other than the second layer portion. Therefore, by setting the inclination angle of the second layer portion to an appropriate angle, generation of polarization charge near the interface between the wall surface of the second layer and the gate insulating film (the channel region) can be suppressed. Therefore, the channel mobility of the nitride semiconductor device can be improved. Accordingly, an excellent transistor operation can be performed. Of course, since the nitride semiconductor device is made of a group III nitride semiconductor, characteristics such as a high withstand voltage, a high-temperature operation, large current density, high-speed switching, and low on-resistance can also be realized as compared to a device made of a silicon semiconductor.

The group III nitride semiconductor is a semiconductor obtained by compounding a group III element and nitrogen, and typical examples thereof include aluminum nitride (AlN), gallium nitride (GaN), and indium nitride (InN). Generally, it can be expressed as AlₓIn_{y}Ga_{1-x-y}N (0≦x≦1, 0≦y≦1, 0≦x+y≦1).

Next, an operation of this nitride semiconductor device is described. For example, first a bias voltage is applied to between the source and the drain such that the drain electrode is positive. Accordingly, a reverse voltage is applied to a pn junction of the interface between the first and second layers. As a result, between the third layer and the first layer, that is, between the source and the drain is nonconductive state (reverse bias state). From this state, when a bias voltage equal to or more than a predetermined voltage value (gate threshold voltage) being positive with respect to the potential of the source electrode regarded as a reference potential is applied to the gate electrode, then electrons are induced near the interface between the wall surface of the second layer and the gate insulating film (the channel region) and an inversion layer (channel) is formed. Then, via the inversion layer, conduction is provided between the source and the drain. Thus, a transistor operation of the nitride semiconductor device is realized.

As described above, the wall surface extending from the first to third layers includes a plurality of portions having different inclination angles, so that the inclination angles of the portions other than the second layer portion can be set regardless of the inclination angle of the second layer portion. In other words, while the inclination angle of the second layer portion is set so as to suppress generation of polarization charge, the inclination angles of portions other than the second layer portion can be properly set to an angle different from the inclination angle of the second layer portion. Therefore, by setting the inclination angles of the portions other than the second layer portion to appropriate angles (for example, angles more gradual than the second layer portion angle to the lamination interface of the nitride semiconductor laminated structure), in the reverse bias state of the nitride semiconductor device, electric field concentration to the portions other than the second layer portion can be suppressed. As a result, occurrence of a breakdown of the portions other than the second layer portion can be prevented.

It is also allowed that, in this nitride semiconductor device, the nitride semiconductor laminated structure includes a mesa-like laminated portion having side wall extending from the first, through the second, to the third layers, and the side wall of the mesa-like laminated portion form the wall surface, and among the upper end portions positioned at the upper ends of the mesa-like laminated portion, lower end portions positioned at the lower ends of the mesa-like laminated portion, and the central portions positioned between the upper end portions and the lower end portions on the side wall of the mesa-like laminated portion, the inclination angle of the central portions is greatest.

According to this configuration, the inclination angle of the central portions of the mesa-like lamination portion is greatest, so that by setting the inclination angles of the upper end portions and the lower end portions to appropriate angles, electric field concentration in the upper end portions and the lower end portions can be prevented in the reverse bias state of the nitride semiconductor device. As a result, occurrence of a breakdown at the upper end portions and the lower end portions can be prevented.

The wall surface of the second layer portion opposed to the gate electrode is preferably a nonpolar plane such as an m-plane (10-10) or an a-plane (11-20), or a semipolar plane such as (10-11), (10-13), or (11-22), or the like. When the wall surface of the second layer portion is a nonpolar or semipolar plane that has high crystal symmetry and is extremely stable, the effect of suppressing generation of polarization charges near the interface between the wall surface and the gate insulating film (the channel region) can be further improved.

In the nitride semiconductor device, it is preferable that the lamination interface of the nitride semiconductor laminated structure is c-plane, and among the plurality of portions having different inclination angles, the inclination angle of the second layer portion is greatest.

With this configuration, the lamination interface of the nitride semiconductor laminated structure is c-plane that is polar plane, and the inclination angle of the second layer portion to the lamination interface of the nitride semiconductor laminated structure is greatest, so that generation of polarization charge at the second layer portion can be further suppressed.

In addition, it is preferable that the nitride semiconductor device further includes a fourth layer formed in the semiconductor surface portion of the second layer portion forming the wall surface and having a different conductive characteristic from that of the second layer.

With this configuration, in the semiconductor surface portion of the second layer portion forming the wall surface, a fourth layer having a different conductive characteristic from that of the second layer is formed. Therefore, the gate insulating film is arranged in contact with this fourth layer, and the gate electrode is opposed to the fourth layer with the gate insulating film sandwiched between the fourth layer and the gate electrode.

Accordingly, during operation of the nitride semiconductor device operates, an inversion layer (channel) is formed in the fourth layer. Therefore, when the fourth layer is a p type semiconductor having a lower acceptor concentration than that of the second layer, for example, the gate threshold voltage can be lowered as compared to a case where the inversion layer is formed in the second layer. Therefore, an excellent nitride semiconductor device can be realized.

The fourth layer may be a p type semiconductor having a lower acceptor concentration than that of the second layer, or may be any of, for example, an n type semiconductor, an i type semiconductor, and a semiconductor containing an n type dopant and a p type dopant. When the fourth layer is an n type semiconductor, in order to realize a normally-off operation of the nitride semiconductor device, the concentration of the n type dopant can be properly controlled.

The method for producing the nitride semiconductor device of the present invention includes a laminating step for forming a nitride semiconductor laminated structure having a laminated structure comprising an n type first layer, a second layer containing a p type dopant, and an n type third layer, each of the laminated structure made of a group III nitride semiconductor, a wall surface forming step for forming a wall surface extending from the first, through the second, to the third layers, and including a plurality of portions having different inclination angles to a lamination interface of the nitride semiconductor laminated structure, a gate insulating film forming step for forming a gate insulating film on the wall surface so as to extend for the first, second, and third layers, a gate electrode forming step for forming a gate electrode so as to be opposed to the wall surface in the second layer with the gate insulating film sandwiched between the gate electrode and the wall surface, a source electrode forming step for forming a source electrode so as to be electrically connected to the third layer, and a drain electrode forming step for forming a drain electrode so as to be electrically connected to the first layer. According to this method, the nitride semiconductor device can be manufactured. The wall surface forming step includes, for example, a step of etching the first, second, and third layers by means of dry etching.

The wall surface forming step preferably includes a step of forming the wall surface so that the wall surface in the second layer portion opposed to the gate electrode is nonpolar or semipolar plane.

In the above-described method for manufacturing the nitride semiconductor device, it is preferable that the laminating step is a step of forming the nitride semiconductor laminated structure using c-plane as lamination interface, and the wall surface forming step is a step of forming the wall surface so that the second layer the inclination has a greatest angle.

It is preferable that the method for producing the nitride semiconductor device further includes a fourth layer forming step for forming a fourth layer in semiconductor surface portions of the second layer portion forming the wall surface exposed by the wall surface forming step, having a different conductive characteristic from that of the second layer.

These and other objects, features and effects of the present invention will be more apparent from the following embodiments described with reference to the accompanying drawings.

### BRIEF DESCRIPTION OF THE SEVERAL VIEWS OF THE DRAWING

FIG. 1A is a diagrammatic sectional view for describing a structure of a field effect transistor according to a first embodiment of the present invention;

FIG. 1B is an enlarged view of the portion enclosed by a dashed line ellipse shown in FIG. 1A;

FIG. 2A is a diagrammatic sectional view of a method for producing the field effect transistor of FIG. 1A in order of steps;

FIG. 2B is a diagrammatic sectional view of the next step of FIG. 2A;

FIG. 2C is a diagrammatic sectional view of the next step of FIG. 2B;

FIG. 2D is a diagrammatic sectional view of the next step of FIG. 2C;

FIG. 2E is a diagrammatic sectional view of the next step of FIG. 2D;

FIG. 3 is a diagrammatic sectional view for describing a structure of a field effect transistor according to a second embodiment of the present invention;

FIG. 4A is a diagrammatic sectional view of a method for producing the field effect transistor of FIG. 3 in order of steps;

FIG. 4B is a diagrammatic sectional view of the next step of FIG. 4A;

FIG. 4C is a diagrammatic sectional view of the next step of FIG. 4B;

FIG. 4D is a diagrammatic sectional view of the next step of FIG. 4C;

FIG. 4E is a diagrammatic sectional view of the next step of FIG. 4D;

FIG. 4F is a diagrammatic sectional view of the next step of FIG. 4E;

FIG. 4G is a diagrammatic sectional view of the next step of FIG. 4F; and

FIG. 5 is a diagrammatic sectional view for describing a structure according to a conventional field effect transistor.

### DETAILED DESCRIPTION OF THE INVENTION

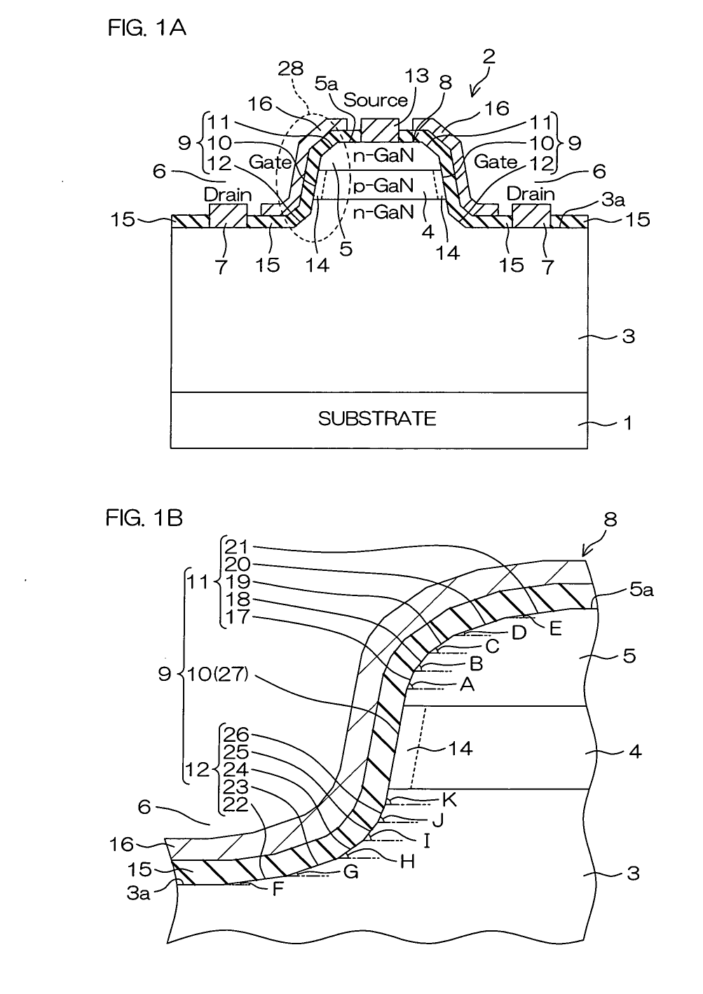

FIG. 1A is a diagrammatic sectional view for describing the structure of a field effect transistor according to a first embodiment of the invention. FIG. 1B is an enlarged view of the portion enclosed by the dashed line ellipse 28 shown in FIG. 1A.

This field effect transistor (nitride semiconductor device) includes a substrate 1 and a nitride semiconductor laminated structure 2 made of a GaN compound semiconductor layer grown on the substrate 1.

For the substrate 1, an insulative substrate such as a sapphire substrate or the like, or a conductive substrate such as a GaN substrate, a ZnO substrate, an Si substrate, a GaAs substrate, an SiC substrate or the like may be applied, for example.

The nitride semiconductor laminated structure 2 includes an n type GaN layer 3 (first layer), a p type GaN layer 4 (second layer), and an n type GaN layer 5 (third layer), and these GaN layers are laminated in this order.

The nitride semiconductor laminated structure 2 is etched in a direction transversing the lamination interfaces to a depth at which the n type GaN layer 3 is exposed from the n type GaN layer 5. Accordingly, drain trenches 6 which penetrate the p type GaN layer 4 from the n type GaN layer 5 and reach the middle of the n type GaN layer 3 are formed. The bottom walls of the drain trenches 6 reaching the middle of the n type GaN layer 3 are formed by extended portions of the n type GaN layer 3 in this embodiment. On the bottom surfaces of the drain trenches 6, that is, on the upper surface 3a of the n type GaN layer 3 (hereinafter, referred to as “the upper surface 3a of the n type GaN layer 3,” simply) parallel to the lamination interfaces of the nitride semiconductor laminated structure 2, drain electrodes 7 are formed in contact with these. The drain electrodes 7 are electrically connected to the n type GaN layer 3.

On the other hand, near the middle portion in the width direction of the nitride semiconductor laminated structure 2, as the drain trenches 6 are formed, mesa-like laminated portions 8 having substantially trapezoid sectional shapes (mesa shapes), and including of the n type GaN layer 3, the p type GaN layer 4, and the n type GaN layer 5 are formed. The side walls of the mesa-like laminated portion 8 (side walls of the drain trench 6) form wall surfaces 9 extending from the n type GaN layer 3, the P type GaN layer 4, to the n type GaN layer 5.

The wall surface 9 has an upper end portion 11 positioned near the boundary with the top surface 5a of the n type GaN layer 5 parallel to the lamination interfaces of the nitride semiconductor laminated structure 2, a lower end portion 12 positioned near the boundary with the upper surface 3a of the n type GaN layer 3, and a central portion 10 positioned between the upper end portion 11 and the lower end portion 12.

The upper end portion 11 is formed into a curved surface shape, and has a plurality of portions having different inclination angles to the lamination interfaces of the nitride semiconductor laminated structure 2 (hereinafter, referred to as “inclination angles,” simply). The inclination angle in this embodiment means the angle on the inside out of the angle on the inside and the angle on the outside of the nitride semiconductor laminated structure 2 by setting the line of intersection of the wall surface 9 and the lamination interface of the nitride semiconductor laminated structure 2 (see FIG. 1B). FIG. 1B is a drawing for describing the inclination angles of the plurality of portions of the wall surface 9, and for convenience of description, tangents to the plurality of portions (five in FIG. 1B for each) of the upper end portion 11 and the lower end portion 12 are continuously shown.

In FIG. 1B, the upper end portion 11 has, in order from the lower side of the lamination direction in the nitride semiconductor laminated structure 2 (hereinafter, referred to as “lamination direction”), a first upper inclined portion 17, a second upper inclined portion 18, a third upper inclined portion 19, a fourth upper inclined portion 20, and a fifth upper inclined portion 21. These inclined portions 17 through 21 are respectively inclined at angles A through E with respect to the lamination interfaces of the nitride semiconductor laminated structure 2.

On the other hand, the lower end portion 12 is formed into a curved surface shape like the upper end portion 11, and has a plurality of portions having different inclination angles. In FIG. 1B, the lower end portion 12 has, in order from the lower side in the lamination direction, a first lower inclined portion 22, a second lower inclined portion 23, a third lower inclined portion 24, a fourth lower inclined portion 25, and a fifth lower inclined portion 26. These inclined portions 22 through 26 are respectively inclined at angles F through J to the lamination interfaces of the nitride semiconductor laminated structure 2.

The central portion 10 has a central inclined portion 27 formed so as to extend from the upper end portion of the n type GaN layer 3, the p type GaN layer 4, to the lower end portion of the n type GaN layer 5. In FIG. 1B, this central inclined portion 27 is continued to the fifth lower inclined portion 26 at the upper end portion of the n type GaN layer 3, and continued to the first upper inclined portion 17 at the lower end portion of the n type GaN layer 5. The central inclined portion 27 is inclined at an angle K to the lamination interfaces of the nitride semiconductor laminated structure 2. In addition, the central inclined portion 27 is formed into a planar shape.

Thus, the wall surface 9 has a plurality of inclined portions 17 through 27 having different inclined angles as a whole. Further, the wall surface 9 is formed so that the inclination angles successively change with regard to the depth position in the lamination direction. Although not shown in FIG. 1B, for example, in a configuration in which each of the inclined portions 22 through 26 of FIG. 1B are further segmentalized, at the lower end portion 12 and the central portion 10, the inclination angles of the lower inclined portions 22 through 26 and the central inclined portion 27 successively change so as to increase from the lower side in the lamination direction. On the other hand, in the configuration in which the inclined portions 17 through 21 in FIG. 1B are further segmentalized, at the central portion 10 and the upper end portion 11, the inclination angles of the central inclined portion 27 and the upper inclined portions 17 through 21 change so as to decrease successively from the lower side in the lamination direction. In other words, the inclination angles of the wall surface 9 successively change so that the inclination angle K of the central inclined portion 27 is the maximum and the inclination angle increases successively at the portion lower than the central inclined portion 27, and decreases successively at the portion higher than the central inclined portion 27.

In the semiconductor surface portion near the wall surface 9 (central inclined portion 27) of the p type GaN layer 4, a region 14 is formed. This region 14 made of a semiconductor having conductive characteristics different from that of the p type GaN layer 4, for example, a p⁻ type semiconductor having an acceptor concentration lower than that of the p type GaN layer 4. The region 14 has a thickness of, for example, several nm to 100 nm in the direction orthogonal to the wall surface 9. The region 14 is not limited to the p⁻ type semiconductor as long as the semiconductor has conductive characteristics different from that of the p type GaN layer 4, and for example, may be made of an n type semiconductor containing an n type dopant, an i type semiconductor rarely containing dopants, or a semiconductor containing the n type and p type dopants. An inversion layer which makes continuity between the n type GaN layer 3 and the n type GaN layer 5 is formed in this region 14 near the interface with the gate insulating film 15 (described later) when an appropriate bias voltage is applied to the gate electrode 16 (described later).

On the top surface 5a of the n type GaN layer 5, a source electrode 13 is formed in contact with this. The source electrode 13 is electrically connected to the n type GaN layer 5.

Further, on the surface of the nitride semiconductor laminated structure 2 (except for the portions where the drain electrode 7 and the source electrode 13 are disposed), a gate insulating film 15 is formed so as to contact this surface. On the gate insulating film 15, gate electrodes 16 are formed opposite to the wall surfaces 9, the edges of the wall surfaces 9 on the top surface 5a of the n type GaN layer 5, and the edges of the wall surfaces 9 on the upper surface 3a of the n type GaN layer 3.

The nitride semiconductor laminated structure 2 is formed by means of, for example, so-called MOCVD (Metal Oxide Chemical Vapor Deposition) on the substrate 1. For example, when a substrate 1 whose principal surface is a c-plane (0001) is used, the nitride semiconductor laminated structure 2 grown by epitaxial growth on this substrate 1, that is, the n type GaN layer 3, the p type GaN layer 4, and the n type GaN layer 5 are laminated by using c-planes (0001) as principal surfaces. Therefore, the lamination interfaces of the nitride semiconductor laminated structure 2, the upper surface 3a of the n type GaN layer 3, and the top surface 5a of the n type GaN layer 5 are c-planes (0001). On the other hand, the central inclined portion 27 of the mesa-like laminated portion 8 inclined at the angle K to the lamination interfaces of the nitride semiconductor laminated structure 2 are planes other than c-planes. For example, the inclination angle K of the central inclined portion 27 of the mesa-like laminated portion 8 is preferably in the range of 15 to 90 degrees. More specifically, the central inclined portion 27 is preferably a nonpolar plane such as an m-plane (10-10) or an a-plane (11-20), or a semipolar plane such as (10-13), (10-11), (11-22), or the like.

The gate insulating film 15 can be composed by using, for example, oxide or nitride. More specifically, it can be composed by using SiO₂ (silicon oxide), Ga₂O₃ (gallium oxide), MgO (magnesium oxide), Sc₂O₃ (scandium oxide), and SiN (silicon nitride), or the like, and in particular, the gate insulating film 15 is preferably composed by using SiO₂ (silicon oxide), SiN (silicon nitride), or both of these.

The gate electrodes 16 can be composed by using, a conductive material such as Pt (platinum), Al (aluminum), Ni/Au (nickel/gold alloy), Ni/Ti/Au (nickel/titanium/gold alloy), Pd/Au (palladium/gold alloy), Pd/Ti/Au (palladium/titanium/gold alloy), Pd/Pt/Au (palladium/platinum/gold alloy), and polysilicon, or the like.

To the drain electrodes 7 and source electrodes 13, a lamination structure made of Ti/Al (lower layer/upper layer) can be applied. In addition, the drain electrodes 7 and the source electrodes 13 may be made of, for example, Mo or an Mo compound (for example, molybdenum silicide), Ti or a Ti compound (for example, titanium silicide), or W or a W compound (for example, tungsten silicide). When the drain electrodes 7 and source electrodes 13 are such a material, excellent contacts can be achieved for wiring (not shown) for providing these electrodes with a bias voltage.

Next, an operation of the field effect transistor will be described.

A bias voltage is applied to the source electrode 13 and the drain electrode 7 such that the drain electrode 7 is positive. Accordingly, a pn junction at the interface between the n type GaN layer 3 and the p type GaN layer 4 is applied a reverse voltage. As a result, between the n type GaN layer 5 and the n type GaN layer 3, that is, between the source and the drain is nonconductive state (reverse bias state). From this state, when a bias voltage equal to or more than a predetermined voltage value (gate threshold voltage) being positive with respect to a potential of the source electrode 13 regarded as a reference potential is applied to the gate electrode 16. Accordingly, electrons are induced near the interface in the region 14 with the gate insulating film 15, and an inversion layer (channel) is formed. Then, via this inversion layer, conduction is provided between the n type GaN layer 3 and the n type GaN layer 5. Thus, conduction is provided between the source and the drain. At this time, the region 14 made of a p-type semiconductor whose acceptor concentration is lower than that of the p type GaN layer 4, so that electrons can be induced in the region 14 by a lower gate threshold voltage. By properly setting the p type dopant concentration in the region 14, between the source and the drain is conductive when an appropriate bias is applied to the gate electrode 16, and on the other hand, when no bias is applied to the gate electrode 16, between the source and the drain is nonconductive. In other words, a normally-off operation is realized.

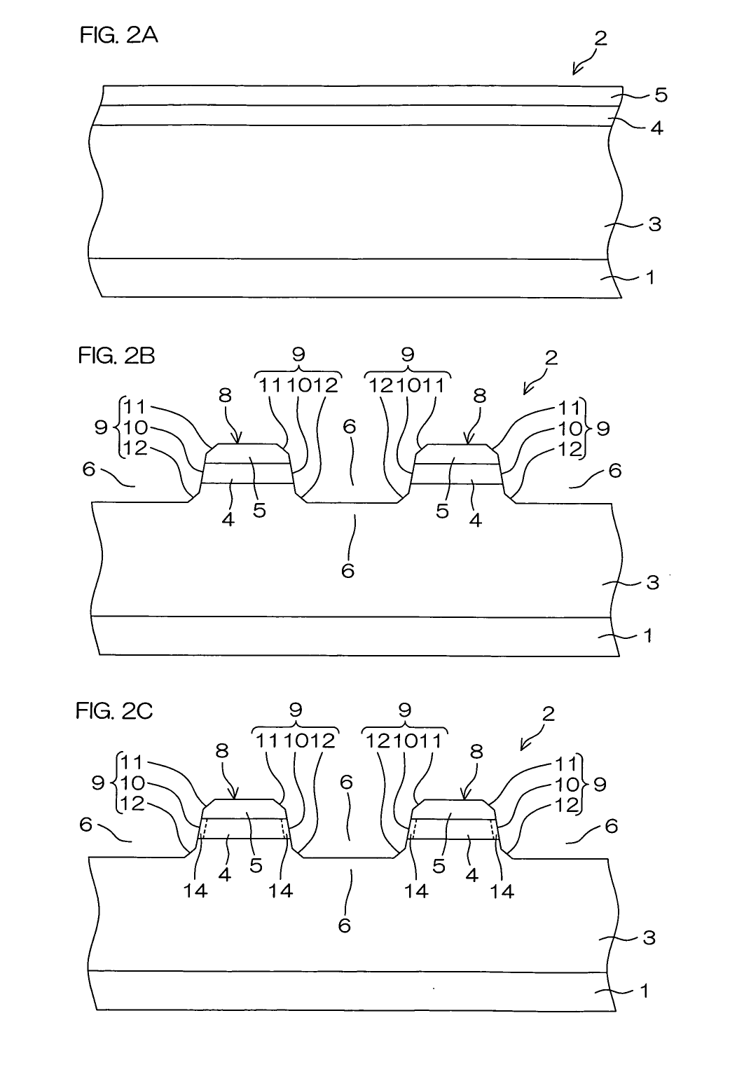

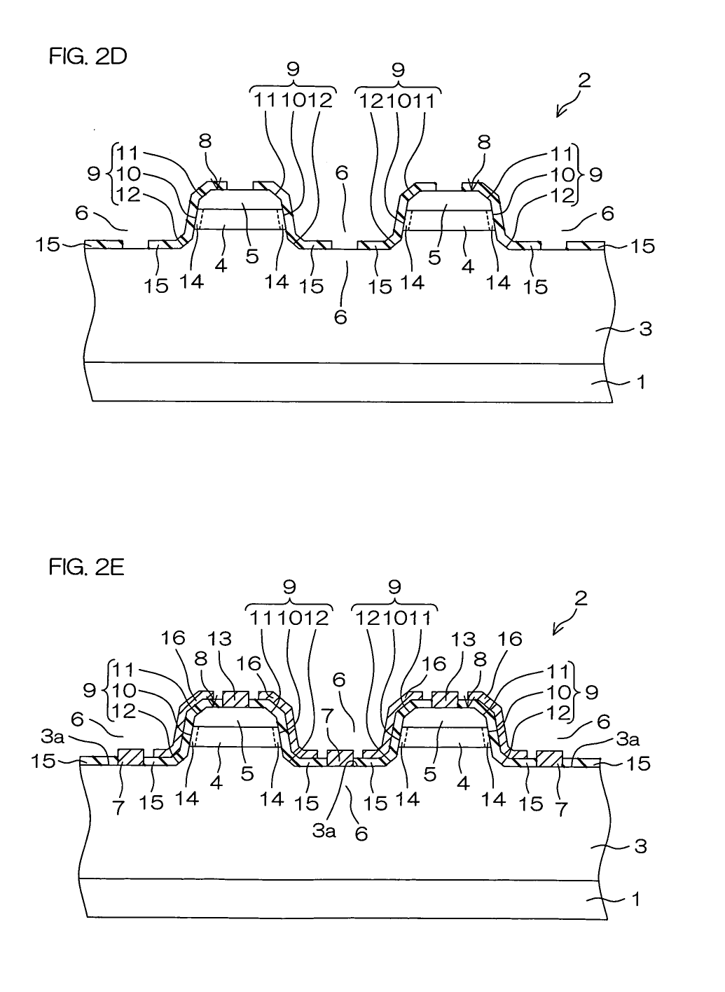

FIG. 2A through FIG. 2E are diagrammatic sectional views showing a method for producing the field effect transistor of FIG. 1A in order of steps.

To produce this field effect transistor, first, as shown in FIG. 2A, on the substrate 1, for example, by means of MOCVD, the n type GaN layer 3, the p type GaN layer 4, and the n type GaN layer 5 are grown in order (laminating step). Thus, the nitride semiconductor laminated structure 2 is formed on the substrate 1. As an n type dopant for growing the n type GaN layer 3 and the n type GaN layer 5, for example, Si or the like is used. As a p type dopant for growing the p type GaN layer 4, for example, Mg, C, or the like is used.

After the formation of the nitride semiconductor laminated structure 2, as shown in FIG. 2B, the nitride semiconductor laminated structure 2 is etched into a stripe pattern (wall surface forming step). Accordingly, drain trenches 6 are formed such that the drain electrode 6 penetrates the p type GaN layer 4 from the n type GaN layer 5 and reach the middle of the n type GaN layer 3. By forming the drain trenches 6, a plurality (only two is shown in FIG. 2B) of striped mesa-like laminated portions 8 are formed on the substrate 1.

The drain trenches 6 can be formed by dry-etching using, for example, a Cl₂/SiCl₄ mixed gas as an etching gas. The Cl₂/SiCl₄ mixed gas is supplied so that Cl₂ is supplied at a predetermined fixed flow rate, and SiCl₄ is supplied at a varying flow rate that successively varies. More specifically, first, Cl₂/SiCl₄ mixed gas is supplied at Cl₂/SiCl₄ flow rates of 50 sccm/25 sccm. After starting supplying, while the Cl₂ flow rate is kept at 50 sccm, the flow rate of SiCl₄ is gradually decrease from 25 sccm to 5 sccm. Then, when the flow rates of the Cl₂/SiCl₄ mixed gas reaches 50 sccm/5 sccm, for example, in the case where the layer thickness of the p type GaN layer 4 is 0.5 micrometers, the gas is supplied for 5 to 6 minutes at the flow rates are 50 sccm/5 sccm. Thereafter, while the Cl₂flowrate is kept at 50 sccm, the flowrate of SiCl₄ is gradually increased from 5 sccm to 25 sccm. Then, when the flow rates of the Cl₂/SiCl₄ mixed gas reach 50 sccm/25 sccm, the supply is stopped. In this formation of the drain trenches 6, the supply time of the Cl₂/SiCl₄ mixed gas at the flow rates of 50 sccm/5 sccm is in proportion to the layer thickness of the p type GaN layer 4.

The etching speed of the Cl₂/SiCl₄ to GaN is increased by decreasing the flow rate of SiCl₄ in the mixed gas. Therefore, in the process of gradually decreasing the flow rate of SiCl₄ from 25 sccm to 5 sccm, the upper end portions 11 of the mesa-like laminated portion 8 are formed, and the inclination angle of the upper end portions 11 to the lamination interfaces of the nitride semiconductor laminated structure 2 successively increases toward the lower side of the lamination direction (etching direction). On the other hand, in the process of gradually increasing the flow rate of SiCl₄ from 5 sccm to 25 sccm, the lower end portions 12 of the mesa-like laminated portion 8 are formed, the inclination angle of the lower end portions 12 to the lamination interfaces of the nitride semiconductor laminated structure 2 successively decreases toward the lower side of the lamination direction (etching direction). In the process in which the flow rate of SiCl₄ is kept at the smallest rate of 5 sccm, the central portions 10 of the mesa-like laminated portion 8 are formed, and the central portions 10 has the central inclined portions 27 (see FIG. 1B) with the greatest inclination angle.

After dry-etching, wet-etching may be performed as appropriate to improve the wall surfaces 9 of the mesa-like laminated portion 8 that was damaged by the dry-etching. For wet-etching, HF (hydrofluoric acid) and HCl (hydrochloric acid), or the like, are preferably used. Accordingly, Si-based oxides and Ga oxides, or the like, are removed and the wall surfaces 9 of the mesa-like laminated portion 8 can be smoothed, so that wall surfaces 9 with less damage can be obtained. By reducing damage on the wall surfaces 9, an excellent crystal state of the regions 14 can be maintained. In addition, the interfaces between the wall surfaces 9 and the gate insulating film 15 can be made excellent, so that the interface state can be reduced. Accordingly, the channel resistance can be reduced and the leak current can be suppressed. Instead of wet-etching, low-damage dry-etching can be applied.

Next, on the nitride semiconductor laminated structure 2, gate insulating films 15 are formed. The gate insulating films 15 are formed by, for example, ECR sputtering (Electron Cyclotron Resonance Sputtering). To form the gate insulating films 15 by ECR sputtering, first, the substrate 1 on which the nitride semiconductor laminated structure 2 was formed is placed in an ECR deposition apparatus, and is irradiated with Ar⁺ plasma having energy of about 30 eV for several seconds, for example. Irradiation of the Ar⁺ plasma alters the semiconductor surface portions near the wall surfaces 9 at the p type GaN layer 4, as shown in FIG. 2C, to form regions 14 having conductive characteristics different from that of the p type GaN layer 4 (fourth layer forming step). In FIG. 1A, FIG. 1B, and FIG. 2, the regions 14 are shown on only the wall surfaces 9 of the p type GaN layer 4, however, in actuality, altered regions are also formed on the wall surfaces 9 of the n type GaN layer 3 and the n type GaN layer 5. However, even if the altered regions are formed on the wall surfaces 9 of these n type GaN layers 3 and n type GaN layer 5, the effect as a device does not change, so that they are not shown in FIG. 1A, FIG. 1B, and FIG. 2.

Thereafter, an insulating film (for example, SiO₂, SiN, etc.) covering the entire surface of the nitride semiconductor laminated structure 2 is formed. After this insulating film is formed, unnecessary portions (portions other than the gate insulating films 15) of the insulating film are removed by etching to form the gate insulating films 15 as shown in FIG. 2D (gate insulating film forming step).

Next, by a known photolithography technique, a photoresist (not shown) having openings in regions where the drain electrodes 7 and the source electrodes 13 should be formed is formed on the gate insulating films 15. Then, from above this photoresist, metals (for example, Ti and Al) to be used as materials of the drain electrodes 7 and the source electrodes 13 are sputtered by a sputtering method in order of Ti and Al. Thereafter, by removing the photoresist, unnecessary portions of the metals (portions other than the drain electrodes 7 and the source electrodes 13) are lifted off together with the photoresist. By these operations, as shown in FIG. 2E, the drain electrodes 7 are formed in contact with the bottom surfaces of the drain trenches 6, that is, the upper surface 3a of the n type GaN layer 3, and the source electrodes 13 are formed in contact with the top surface 5a of the n type GaN layer 5 (drain electrode forming step, source electrode forming step). After the formation of the drain electrodes 7 and the source electrodes 13, thermal alloying (annealing) is performed, whereby the contact between the drain electrodes 7 and the n type GaN layer 3 and the contact between the source electrode 13 and the n-type GaN layer 5 form ohmic contact.

Thereafter, according to the same method as in the case of the drain electrodes 7 and the source electrodes 13, as shown in FIG. 2E, gate electrodes 16 are formed so as to oppose to the wall surfaces 9, the edges of the wall surfaces 9 on the top surface 5a of the n type GaN layer 5, and the edges of the wall surfaces 9 on the upper surface 3a of the n type GaN layer 3 are formed with the gate insulating films 15 sandwiched between these portions and the gate electrode 16 (gate electrode forming step). Thus, a field effect transistor having the structure shown in FIG. 1A is obtained.

The plurality of mesa-like laminated portions 8 formed on the substrate 1 form unit cells, each. The gate electrodes 16, the drain electrodes 7, and the source electrodes 13 of the nitride semiconductor laminated structure 2 are mutually connected at positions not shown, respectively. The drain electrode 7 can be shared by mesa-like laminated portions 8 adjacent to each other.

As described above, in this embodiment, the wall surface 9 includes a plurality of inclined portions 17 through 27 having different inclination angles, so that the inclination angle of the central inclined portion 27 into a planar shape can be set regardless of the inclination angles of the portions other than the central inclined portion 27 (inclined portions 17 through 26 in FIG. 1B). Therefore, as in this embodiment, among the inclined portions (inclined portions 21 through 27 in FIG. 1B) forming the wall surface 9, the central inclined portion 27 can be set as a nonpolar plane or semipolar plane that has the greatest inclination angle and high crystal symmetry and is extremely stable. Therefore, generation of polarization charge near the interfaces between the regions 14 and the gate insulating films 15 can be suppressed, and the channel mobility of the field effect transistor can be improved. As a result, an excellent transistor operation can be performed. Of course, since the field effect transistor is made of a group III nitride semiconductor, characteristics such as high withstand voltage, high-temperature operation, large current density, high-speed switching, and low on-resistance can be realized as compared to a device made of a silicon semiconductor.

Further, in this embodiment, the inclination angles of the inclined portions other than the central inclined portion 27 on the wall surface 9 (inclined portions 17 through 26 in FIG. 1B) are smaller than the inclination angle of the central inclined portion 27. In other words, the inclined portions other than the central inclined portion 27 are inclined more gradual than the central inclined portion 27 to the lamination interfaces of the nitride semiconductor laminated structure 2. Therefore, by setting the inclination angles (inclination angles A through J in FIG. 1B) of these inclined portions to appropriate angles, even when the central inclined portion 27 is a nonpolar plane (with an inclination angle of 90 degrees), in the reverse bias state of the field effect transistor, electric field concentration with respect to the upper end portion 11 and the lower end portion 12 can be prevented. Therefore, occurrence of a breakdown in the upper end portion 11 and the lower end portion 12 can be suppressed.

In this embodiment, in the semiconductor surface portion near the wall surface 9 (central inclined portion 27) of the p type GaN layer 4, a region 14 is formed. The gate electrode 16 is opposed to the region 14 with the gate insulating film 15 sandwiched between the region 14 and the gate electrode 16. Therefore, when the field effect transistor operates, an inversion layer (channel) is formed near the interface between the region 14 and the gate insulating film 15. Further, this region 14 is, for example, a p-type semiconductor, an n type semiconductor, an i type semiconductor, or a semiconductor containing n type and p type dopants. Therefore, the gate voltage value necessary for forming the inversion layer (channel) can be reduced. As a result, while the acceptor concentration of the p type GaN layer 4 is kept high so as to prevent reach-through breakdown, the gate threshold voltage can be reduced. Thus, an excellent transistor operation can be performed, and an excellent power device is realized.

In FIG. 1B, the central inclined portion 27 is shown as a single plane, however, in a configuration in which the inclination angle of the portion of the p type GaN layer 4 is greatest, the central inclined portion may have a plurality of planes, or may have both a plane portion and a curved portion. In FIG. 1B, as an example of the plurality of portions of the upper end portion 11 and the lower end portion 12, five portions (inclined portions 17 through 21 and inclined portions 22 through 26) are shown, respectively, however, these inclined portions can be further segmentalized.

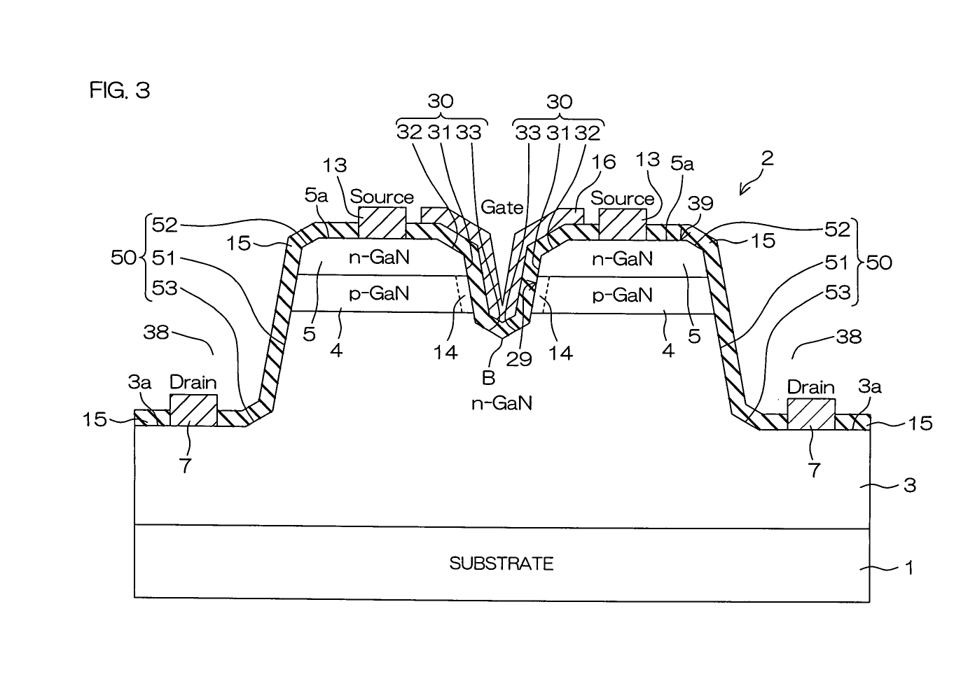

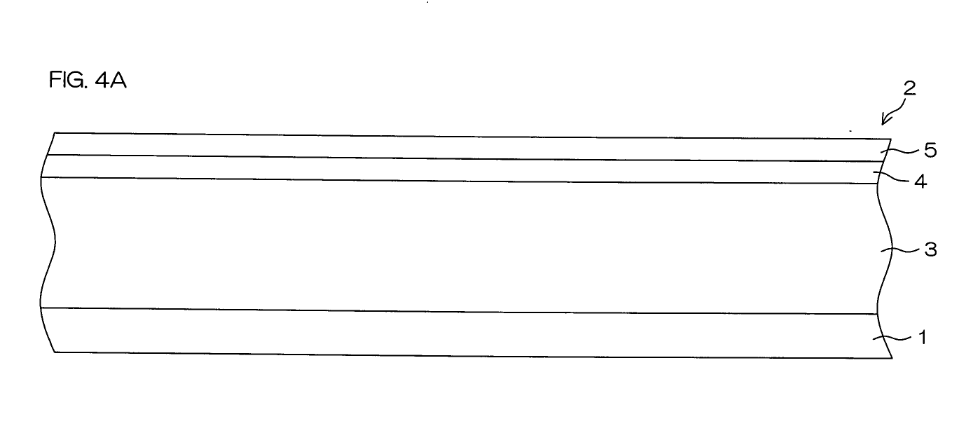

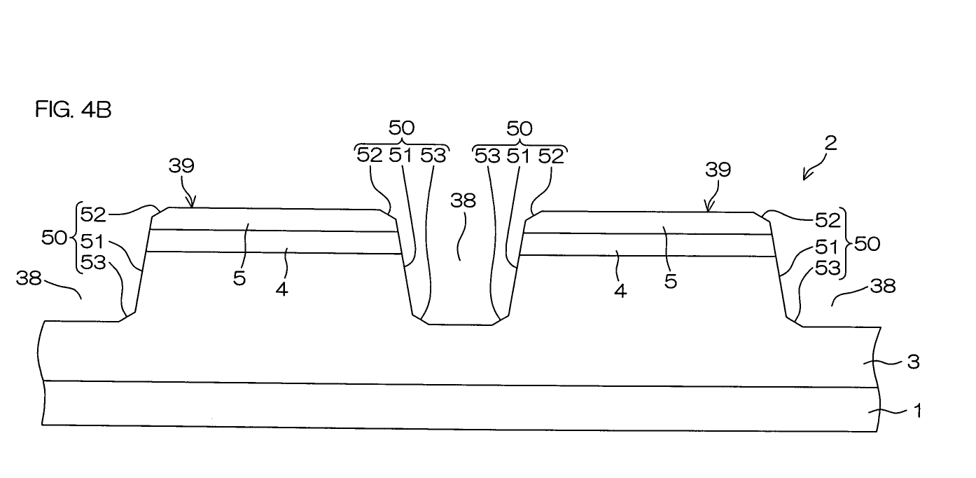

FIG. 3 is a diagrammatic sectional view for describing the structure according to a field effect transistor of a second embodiment of the present invention. In this FIG. 3, portions corresponding to the respective portions shown in FIG. 1A described above are attached with the same reference numerals.

In this embodiment, the nitride semiconductor laminated structure 2 is etched in a direction transversing the lamination interfaces to a depth at which the n type GaN layer 3 is exposed from the n type GaN layer 5. Accordingly, in the nitride semiconductor laminated structure 2, drain trenches 38 are formed so as to penetrate the p type GaN layer 4 from the n type GaN layer 5 and reach the middle of the n type GaN layer 3. The bottom wall of the drain trench 38 reaching the middle of the n type GaN layer 3 is formed by an extended portion of the n type GaN layer 3 in this embodiment. On the bottom surfaces of the drain trenches 38, that is, on the upper surface 3a of the n type GaN layer 3 parallel to the lamination interfaces on the nitride semiconductor laminated structure 2, drain electrodes 7 are formed in contact with these. The drain electrodes 7 are electrically connected to the n type GaN layer 3.

On the other hand, near the middle in the width direction of the nitride semiconductor laminated structure 2, as the drain trenches 38 are formed, mesa-like laminated portions 39 including the n type GaN layer 3, the p type GaN layer 4, and the n type GaN layer 5 and having a substantially trapezoid sectional shape (mesa shape) are formed.

Side walls of the mesa-like laminated portion 39 (side walls of the drain trenches 38) form wall surfaces 50 extending from the n type GaN layer 3, the p type GaN layer 4, to the n type GaN layer 5. This wall surface 50 has an upper end portion 52 positioned near the boundary with the top surface 5a of the n type GaN layer 5 parallel to the lamination interfaces of the nitride semiconductor laminated structure 2, a lower end portion 53 positioned near the boundary with the upper surface 3a of the n type GaN layer 3, and a central portion 51 positioned between the upper end portion 52 and the lower end portion 53. The upper end portion 52, the lower end portion 53, and the central portion 51 are formed similar to the upper end portion 11, the lower end portion 12, and the central portion 10. Therefore, the wall surface 50 has a plurality of inclined portions having different inclination angles like, for example, the inclined portions 17 through 27 shown in FIG. 1B as a whole. By thus forming the wall surfaces 50, the coating performance of the gate insulating film 15 to the wall surfaces 50 can be improved. The wall surface 50 may be formed of a single plane inclined in a range of, for example, 15 to 90 degrees with respect to the lamination interfaces of the nitride semiconductor laminated structure 2.

The mesa-like laminated portion 39 is etched in a direction transversing the lamination interfaces to a depth where the n type GaN layer 3 is exposed from the n type GaN layer 5 near the middle of the width direction. Accordingly, near the middle in the width direction of the mesa-like laminated portion 39, a gate trench 29 is formed so as to penetrate the p type GaN layer 4 from the n type GaN layer 5 and reach the middle of the n type GaN layer 3. The gate trench 29 has a substantially V sectional shape. The gate trench 29 is formed in a stripe pattern along the stripe direction of the drain trenches 38 to a depth shallower than the depth of the bottom surfaces of the drain trenches 38 from the surface of the n type GaN layer 5.

One side wall and the other side wall of the gate trench 29 having the substantially V sectional shape are opposed to each other. The lower end of one side wall and the lower end of the other side wall form a ridge B along the stripe direction of the gate trench 29 on the bottom wall (n type GaN layer 3) of the gate trench 29. These side walls of the gate trenches 29 form wall surfaces 30 extending from the n type GaN layer 3, the p type GaN layer 4, to the n type GaN layer 5. The wall surface 30 has an upper end portion 32 positioned near the boundary with the top surface 5a of the n type GaN layer 5 parallel to the lamination interfaces of the nitride semiconductor laminated structure 2, a lower end portion 33 positioned near the ridge B, and a central portion 31 positioned between the upper end portion 32 and the lower end portion 33. The upper end portion 32, the lower end portion 33, and the central portion 31 are formed similar to the upper end portion 11, the lower end portion 12, and the central portion 10, respectively. Therefore, the wall surface 30 has a plurality of inclined portions having different inclination angles like, for example, the inclined portions 17 through 27 shown in FIG. 1B as a whole. Further, these inclined portions are formed so that the inclination angle of the inclined portion of the central portion 31 is greatest. In the semiconductor surface portions near the wall surfaces 30 of at the p type GaN layer 4, regions 14 are formed.

On the surface of the nitride semiconductor laminated structure 2 including the wall surfaces 30 of the gate trench 29 (except for the portions where the drain electrode 7 and the source electrode 13 are disposed), a gate insulating film 15 is formed so as to be in contact with this surface. On this gate insulating film 15, a gate electrode 16 is formed so as to be opposed to the wall surfaces 30 and the edges of the gate trench 29 on the top surface 5a of the n type GaN layer 5 with the gate insulating film 15 sandwiched between these portions and the gate electrode 16.

Other constructional points are the same as in the first embodiment. In addition, the same operation as of the field effect transistor of the first embodiment can be performed even by the field effect transistor of this second embodiment, so that the same effect as in the field effect transistor of the first embodiment can be obtained.

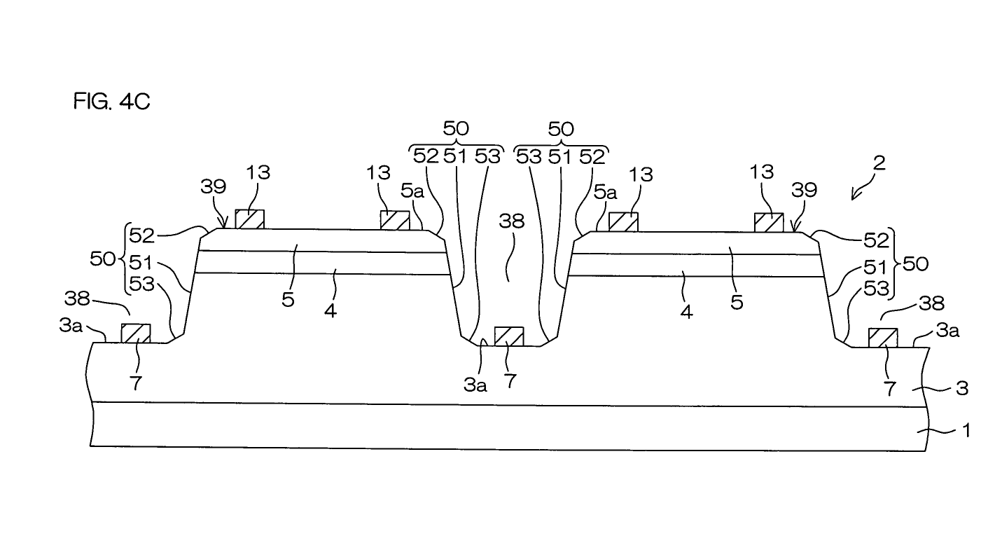

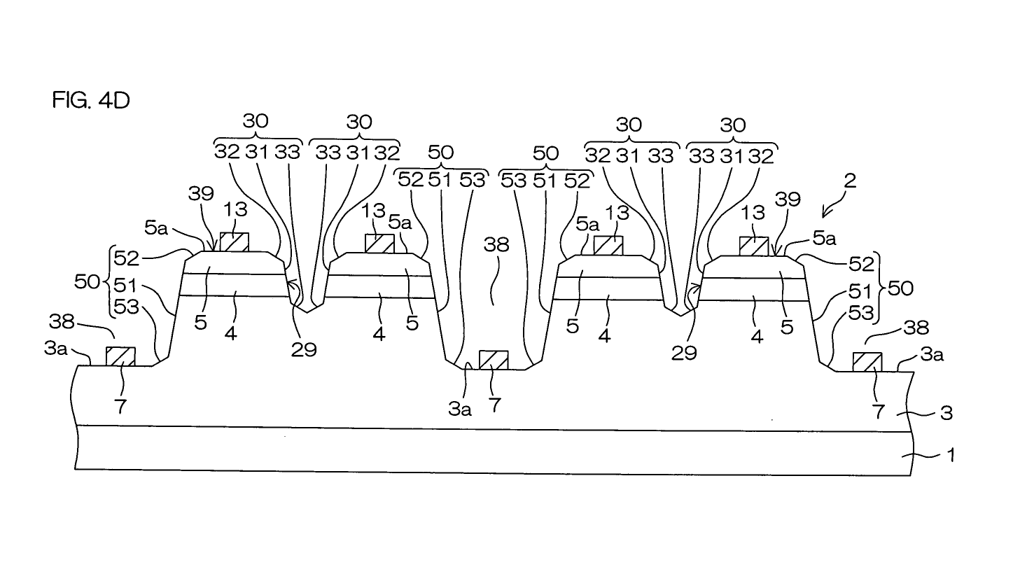

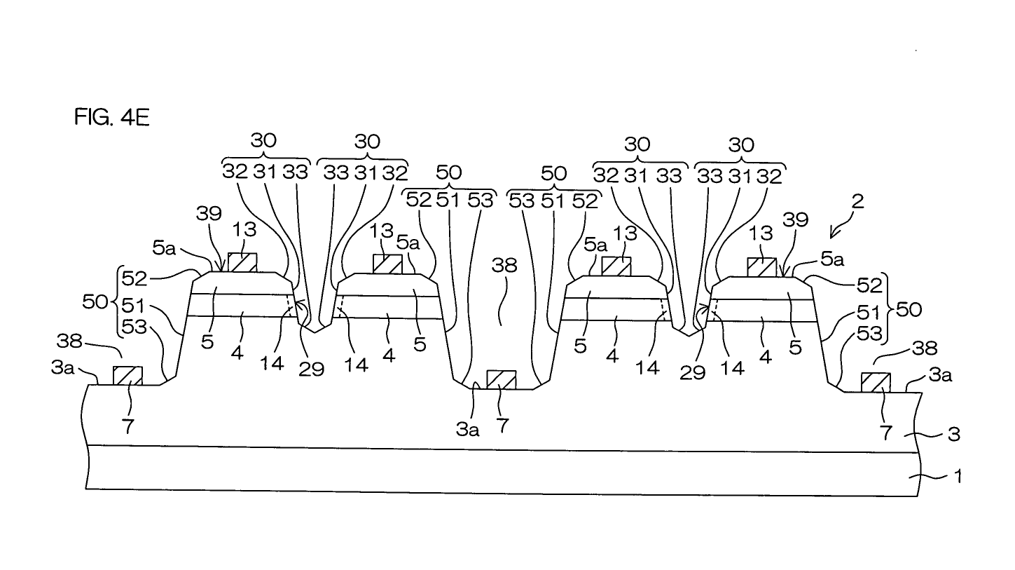

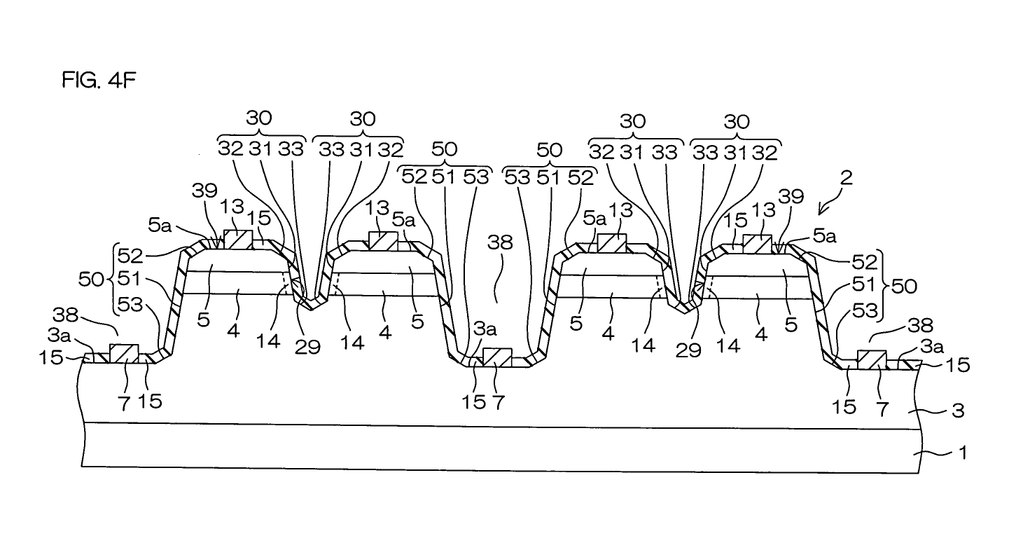

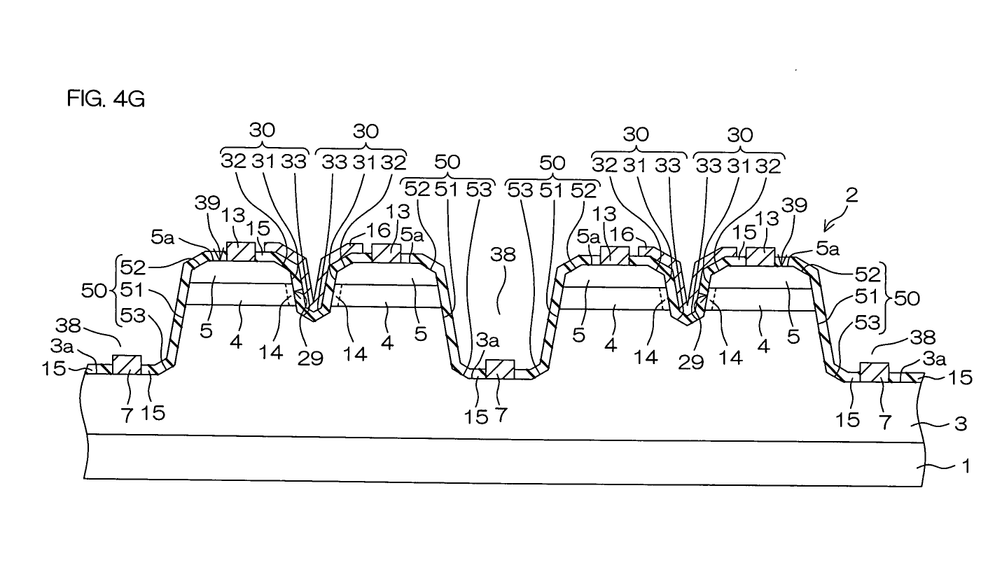

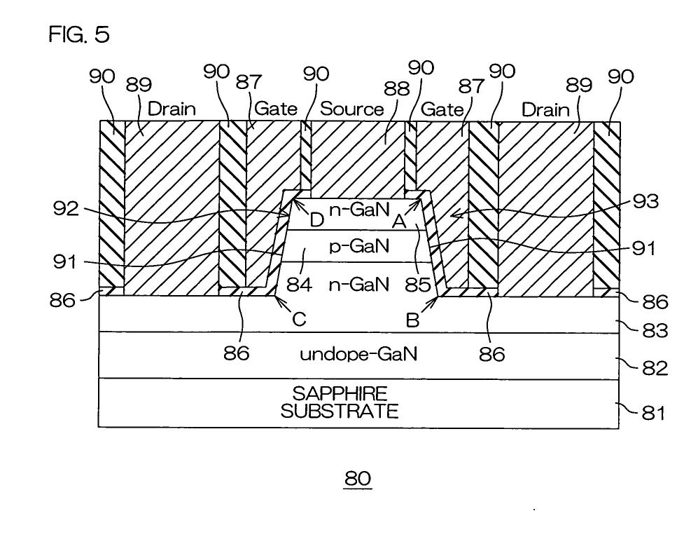

FIG. 4A through FIG. 4G are diagrammatic sectional views showing a method for producing the field effect transistor of FIG. 3 in order of steps.

To produce this field effect transistor, first, as shown in FIG. 4A, the n type GaN layer 3, the p type GaN layer 4, and the n type GaN layer 5 are grown in order on the substrate 1 by means of, for example, MOCVD (laminating step). Thus, the nitride semiconductor laminated structure 2 is formed on the substrate 1.

After the formation of the nitride semiconductor laminated structure 2, as shown in FIG. 4B, the nitride semiconductor laminated structure 2 is etched in a stripe pattern. Accordingly, the drain trenches 38 having wall surfaces 50 extending from the n type GaN layer 3, the p type GaN layer 4, to then type GaN layer 5 are formed. By forming the drain trenches 38, a plurality (only two are shown in FIG. 4B) of mesa-like laminated portions 39 in a stripe pattern are formed on the substrate 1. The drain trenches 38 can be formed by dry-etching using a Cl₂/SiCl₄ mixed gas as an etching gas similar to the drain trench 6 shown in the first embodiment. In other words, in the formation of the drain trenches 38, the Cl₂/SiCl₄ mixed gas is supplied so that, for example, Cl₂ is supplied at a predetermined fixed flow rate and SiCl₄ is supplied at a varying flow rate that successively varies. By thus controlling the flow rates of the Cl₂/SiCl₄, the drain trenches 38 each having the upper end portion 52, the central portion 51, and the lower end portion 53 are formed.

Next, by a known photolithography technique, a photoresist (not shown) having openings in regions where the drain electrodes 7 and the source electrodes 13 should be formed is formed. Then, from above this photoresist, metals (for example, Ti and Al) to be used as materials of the drain electrodes 7 and the source electrodes 13 are sputtered by a sputtering method in order of Ti and Al. Thereafter, the photoresist is removed and unnecessary portions of the metals (portions other than the drain electrodes 7 and the source electrodes 13) are lifted off together with the photoresist. By these operations, as shown in FIG. 4C, on the bottom surfaces of the drain trenches 38, that is, on the upper surface 3a of the n type GaN layer 3, drain electrodes 7 are formed in contact with this surface, and on the top surfaces 5a of the n type GaN layer 5, source electrodes 13 are formed in contact with this surface (drain electrode forming step, source electrode forming step). After the formation of the drain electrodes 7 and the source electrodes 13, thermal alloying (annealing) is performed, and accordingly, the contact between the drain electrodes 7 and the n type GaN layer 3 and the contact between the source electrodes 13 and the n type GaN layer 5 form ohmic contacts.

Next, as shown in FIG. 4D, the mesa-like laminated portions 39 are etched in a stripe pattern along the stripe direction of the drain trenches 38 near the middle portions in the width direction (wall surface forming step). Accordingly, gate trenches 29 having V sectional shape which penetrate the p type GaN layer 4 from the n type GaN layer 5 and reach the middle of the n type GaN layer 3 are formed. The gate trenches 29 can be formed by dry-etching using the Cl₂/SiCl₄ mixed gas as an etching gas as in the case of the drain trenches 6 shown in the first embodiment. In other words, in this formation of the gate trenches 29, the Cl₂/SiCl₄ mixed gas is supplied so that, for example, Cl₂ is supplied at a predetermined fixed flow rate and SiCl₄ is supplied at a varying flow rate that successively varies. By thus controlling the flow rates of the Cl₂/SiCl₄ mixed gas, the gate trenches 29 each having an upper end portion 32, a central portion 31, and a lower end portion 33 are formed.

Next, on the nitride semiconductor laminated structure 2, gate insulating films 15 are formed. The gate insulating films 15 are formed by, for example, ECR sputtering. To form the gate insulating films 15 by ECR sputtering, first, the substrate 1 on which the nitride semiconductor laminated structure 2 was formed is placed in an ECR deposition apparatus, and is irradiated with Ar⁺ plasma with energy of 30 eV for several seconds, for example. Irradiation of the Ar⁺ plasma alters the semiconductor surface portions near the wall surfaces 9 in the p type GaN layer 4, as shown in FIG. 4E, to form regions 14 having conductive characteristics different from that of the p type GaN layer 4 (fourth layer forming step).

Thereafter, an insulating film (for example, SiO₂, SiN, or the like) covering the entire surface of the nitride semiconductor laminated structure 2 is formed. Then, unnecessary portions of this insulating film (portions other than the gate insulating films 15) are removed by etching to form the gate insulating films 15 as shown in FIG. 4F (gate insulating film forming step).

Then, as shown in FIG. 4G, according to the same method as in the case of the drain electrodes 7 and the source electrodes 13, gate electrodes 16 opposed to the wall surfaces 30 and edges of the wall surfaces 30 on the top surfaces 5a of the n type GaN layer 5 across the gate insulating films 15 are formed (gate electrode forming step).

Thus, the field effect transistor structured as shown in FIG. 3 is obtained. The plurality of mesa-like laminated portions 39 formed on the substrate 1 form unit cells, each. The gate electrodes 16, the drain electrodes 7, and the source electrodes 13 of the nitride semiconductor laminated structure 2 are mutually connected at positions not shown, respectively. The drain electrode 7 can be shared by the mesa-like laminated portions 39 adjacent to each other.

The plurality of embodiments of the present invention are described above, and the present invention can also be carried out according to still other embodiments.

For example, in the above-described embodiments, the wall surfaces 9 and the wall surfaces 30 opposed to the gate electrodes 16 have the upper end portion 11 and the upper end portion 32 each having curved surface shape, and the lower end portion 12 and the lower end portion 33 each having curved surface shape. The wall surfaces 9 and the wall surfaces 30 may have another shape as long as the inclination angles in the central portion 10 and the central portion 31 are greatest. For example, the wall surfaces 9 and the wall surfaces 30 may have upper end portions and lower end portions each having a plurality of inclined planes with different inclination angles. However, in the field effect transistor of the present invention, the wall surfaces 9 and the wall surfaces 30 preferably have upper end portions and lower end portions each having curved surface shape. To form the upper end portions and lower end portions each having curved surface shape, the SiCl₄ flow rates of the Cl₂/SiCl₄ mixed gas are only controlled, so that the wall surfaces 9 and the wall surfaces 30 can be formed more easily than in the case where the upper end portions and the lower end portions having a plurality of inclined planes.

In the embodiments described above, the regions 14 are formed in the semiconductor surface portions near the wall surfaces 9 and the wall surfaces 30 of the p type GaN layer 4, however, these regions 14 may not be formed.

In the embodiments described above, the gate insulating films 15 are formed by ECR sputtering, however, without limiting to ECR sputtering, they may be formed by magnetron sputtering. Even when the gate insulating films 15 are formed by magnetron sputtering, the regions 14 can be formed when forming the gate insulating films 15. In addition to the step of forming the gate insulating films 15, it is also allowed that a step of irradiating the regions of the wall surfaces 9 and the wall surfaces 30 of the p type GaN layer 4 with plasma or electron beam or a step of ion implantation into the regions of the wall surfaces 9 and the wall surfaces 30 of the p type GaN layer 4 are further provided and the regions 14 are formed through these steps.

In the embodiments described above, the nitride semiconductor laminated structure 2 is required to have at least an n type group III nitride semiconductor layer, a conductive group III nitride semiconductor layer containing a p type dopant, and an n type group III nitride semiconductor layer, and for example, in addition to the n type GaN layer 3, the p type GaN layer 4, and the n type GaN layer 5, an n type AlGaN layer, or the like, may be formed in contact between the substrate 1 and the n type GaN layer 3.

In the embodiments described above, the drain trenches 6 and the drain trenches 38 are formed to a depth which penetrates the p type GaN layer 4 from the n type GaN layer 5 and reaches the middle of the n type GaN layer 3, however, the depth is not especially limited as long as the drain electrodes 7 and the n type GaN layer 3 can be electrically connected to each other. For example, in a configuration in which an n type AlGaN layer is further formed between the substrate 1 and the n type GaN layer 3, the drain trenches may be formed to a depth which penetrates the n type GaN layer 3 and reaches the middle of the n type AlGaN layer. It is also allowed that the source electrodes 13 are not in contact with the n type GaN layer 5 as long as the n type GaN layer 5 and the source electrodes 13 can be electrically connected to each other, and for example, a GaN layer may be further interposed between the source electrodes 13 and the n type GaN layer 5.

In the embodiments described above, as a method for growing the nitride semiconductor laminated structure 2, MOCVD is applied, however, the method is not especially limited as long as the n type GaN layer 3, the p type GaN layer 4, and the n type GaN layer 5 can be grown, and for example, methods such as LPE (Liquid Phase Epitaxy), VPE (Vapor Phase Epitaxy), and MBE (Molecular Beam Epitaxy) may be applied.

Although the embodiments of the present invention are described in detail, these embodiments are merely specific examples used for clarifying the technical contents of the present invention. Therefore, the present invention should not be construed as being limited in any way to these specific examples. The spirit and scope of the present invention are limited only by the scope of the appended claims.

This application corresponds to Japanese Patent Application No. 2007-158800 filed with the Japanese Patent Office on Jun. 15, 2007, the full disclosure of which is incorporated herein by reference.

What is claimed is:

1. A nitride semiconductor device comprising:
a nitride semiconductor laminated structure comprising an n type first layer, a second layer containing a p type dopant laminated on the first layer, and an n type third layer laminated on the second layer, each layer of the nitride semiconductor laminated structure made of a group III nitride semiconductor, and the nitride semiconductor laminated structure having a wall surface extending from the first, through the second, to the third layers;
a gate insulating film formed on the wall surface such that the gate insulating film extends for the first, second, and third layers;
a gate electrode formed such that the gate electrode is opposed to the wall surface of the second layer with the gate insulating film sandwiched between the gate electrode and the wall surface;
a source electrode electrically connected to the third layer; and
a drain electrode electrically connected to the first layer,
the wall surface including a plurality of portions having different inclination angles to a lamination interface of the nitride semiconductor laminated structure.

2. The nitride semiconductor device according to claim 1, wherein
the wall surface of the second layer portion opposed to the gate electrode is a nonpolar or semipolar plane.

3. The nitride semiconductor device according to claim 1, wherein
the lamination interface of the nitride semiconductor laminated structure is c-plane, and
among the plurality of portions having different inclination angles, the inclination angle of the second layer portion is greatest.

4. The nitride semiconductor device according to claim 1, further comprising:
a fourth layer formed in a semiconductor surface portion of the second layer portion forming the wall surface, and having a different conductive characteristic from that of the second layer.

5. A method for producing a nitride semiconductor device comprising:
a laminating step for forming a nitride semiconductor laminated structure having a laminated structure comprising an n type first layer, a second layer containing a p type dopant, and an n type third layer, each of the laminated structure made of a group III nitride semiconductor;
a wall surface forming step for forming a wall surface extending from the first, through the second, to the third layers, and including a plurality of portions having different inclination angles to a lamination interface of the nitride semiconductor laminated structure;
a gate insulating film forming step for forming a gate insulating film on the wall surface so as to extend for the first, second, and third layers;
a gate electrode forming step for forming a gate electrode so as to be opposed to the wall surface in the second layer with the gate insulating film sandwiched between the gate electrode and the wall surface;
a source electrode forming step for forming a source electrode so as to be electrically connected to the third layer; and
a drain electrode forming step for forming a drain electrode so as to be electrically connected to the first layer.

6. The method for producing a nitride semiconductor device according to claim 5, wherein
the wall surface forming step includes a step of forming the wall surface so that the wall surface in second layer portion opposed to the gate electrode is nonpolar or semipolar plane.

7. The method for producing a nitride semiconductor device according to claim 5, wherein
the laminating step is a step of forming the nitride semiconductor laminated structure using c-plane as the lamination interface, and
the wall surface forming step is a step of forming the wall surface so that the second layer inclination has a greatest angle.

8. The method for producing a nitride semiconductor device according to claim 5, further comprising:
a fourth layer forming step for forming a fourth layer in semiconductor surface portions of the second layer portion in the wall surface exposed by the wall surface forming step, having a different conductive characteristic from that of the second layer.
